(19) United States
(12) Patent Application Publication
(10) Pub. No.: US 2026/0052979 A1
(43) Pub. Date: Feb. 19, 2026

(54) SEMICONDUCTOR STRUCTURE AND METHOD OF MANUFACTURING THE SAME

(71) Applicant: Winbond Electronics Corp., Taichung City (TW)

(72) Inventors: Hao-Chuan CHANG, Taichung City (TW); Jiun-Sheng YANG, Taichung City (TW)

(21) Appl. No.: 19/297,521

(22) Filed: Aug. 12, 2025

(30) Foreign Application Priority Data
Aug. 13, 2024 (TW) 113130299

(51) Int. Cl. H01L 23/528; H01L 21/768; H10B 12/00

(52) U.S. Cl. CPC H01L 23/5283; H01L 21/76877; H10B 12/488

(57) ABSTRACT

A semiconductor structure includes a substrate and a plurality of word lines. The substrate includes an array region, a periphery region surrounding the array region, and a dummy region between the array region and the periphery region. The array region has a plurality of active regions that are separated from each other by an isolation structure. The dummy region has a dummy pattern. The word lines are buried in the substrate. Each word line extends in the first direction, and the word lines are arranged in the second direction. Each word line has a dummy extending portion that extends into the substrate at the intersection with the dummy pattern. Those dummy extending portions of the word lines are arranged in the second direction.

### CROSS REFERENCE TO RELATED APPLICATIONS

This application claims priority of Taiwan Patent Application No. 113130299, filed on Aug. 13, 2024, the entirety of which is incorporated by reference herein.

### BACKGROUND

### Field of the Invention

The disclosure relates to semiconductor structures and methods of manufacturing the same, and, in particular, it relates to methods and structures designed for reducing word line disconnection and improving semiconductor yield.

### Description of the Related Art

As device manufacturing technology continues to shrink, numerous challenges arise. In particular, as the size and spacing of the active regions in the substrate decrease, their aspect ratio increases, making the active regions more prone to bending at the edges of the array region. If this bending occurs, it may affect the alignment between the active regions and the word lines, and could even disrupt the electrical connection between them. To address this issue of bending, a larger dummy pattern is conventionally designed at the edge of the array region in the substrate. However, as the dummy pattern area increases—for example, during the fabrication of dynamic random access memory (DRAM) devices with buried word lines-certain process-related factors, such as the etching loading effect during gate trench formation, may cause the substrate in the dummy region (which is located at the edge of the array region and adjacent to the peripheral region) to protrude. This protrusion may, in turn, lead to disconnection of the word line formed in the subsequent gate trench.

### SUMMARY

Some embodiments of the present disclosure provide semiconductor structures and methods for manufacturing the same, which can improve the aforementioned problems of active region bending and buried word line disconnection.

Some embodiments of the present disclosure provide a semiconductor structure including a substrate and a plurality of word lines. The substrate includes an array region, a periphery region surrounding the array region, and a dummy region between the array region and the periphery region. The array region includes a plurality of active regions that are separated from each other by an isolation structure. The dummy region includes a dummy pattern. The word lines are buried in the substrate. Each of the word lines extends in the first direction, and the word lines are arranged in the second direction. Each of the word lines has a dummy extending portion that extends into the substrate at the intersection with the dummy pattern, and the dummy extending portions of the word lines are arranged in the second direction.

Some embodiments of the present disclosure provide a method of manufacturing a semiconductor structure. The method includes providing a substrate. The substrate includes an array region, a periphery region surrounding the array region, and a dummy region between the array region and the periphery region. The array region includes a plurality of active regions that are separated from each other by an isolation structure. The dummy region includes a dummy pattern. The method further includes forming a plurality of word lines buried in the substrate, wherein each of the word lines extends in a first direction, and the word lines are arranged in a second direction, wherein each of the word lines has a dummy extending portion that extends into the substrate at the intersection with the dummy pattern, and the dummy extending portions of the word lines are arranged in the second direction.

The semiconductor structures and the methods of manufacturing the same according to the present disclosure can facilitate precise alignment between the active regions and the word lines. In addition, this approach can reduce electrical resistance of the word line, leading to faster signal transmission and lower power loss, and can reduce the risk of word line breakage in dummy region, thereby improving the yield of the semiconductor structure.

### BRIEF DESCRIPTION OF THE DRAWINGS

FIG. 1 is a fragmentary plan view of a semiconductor structure, in accordance with an embodiment.

FIGS. 2A, 2B, 2C, 2D, 2E, 2F, 2G, and 2H are cross-sectional views of a semiconductor structure at various intermediate manufacturing stages, in accordance with an embodiment.

FIGS. 3A-3B are cross-sectional views of a semiconductor structure at various intermediate manufacturing stages, in accordance with another embodiment.

### DETAILED DESCRIPTION

This disclosure presents various examples for implementing features of the subject matter. The examples described are illustrative, not limiting. For instance, when a first feature is formed over or on a second, it may involve direct contact or include intermediate features. Reference numerals or letters may be repeated for clarity, without implying relationships between embodiments. Common steps and structures are omitted for brevity.

Further, in some of the following embodiments, the semiconductor structure may be a portion of a DRAM, and other portions of the DRAM may be fabricated using a known DRAM device, but the present invention is not limited thereto. The present invention is applicable to any semiconductor device having a buried word line intersecting a dummy pattern. Although the figures only depict a portion of the array region and a portion of the peripheral region adjacent to the array region for illustrative purposes, the present disclosure is not limited to the components shown.

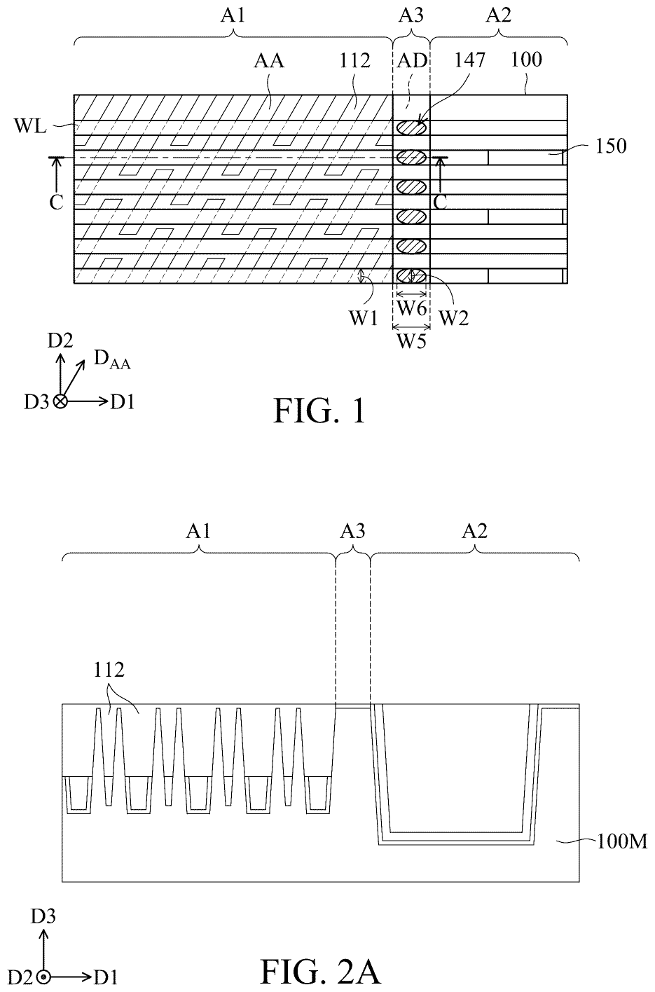

As shown in FIG. 1, a fragmentary plan view of a semiconductor structure of the present disclosure is shown. The semiconductor structure includes a substrate 100 and a plurality of word lines WL. The substrate 100 includes an array region A1, a dummy region A3, and a peripheral region A2. The dummy region A3 is located between the array region A1 and the peripheral region A2. The array region A1 has a plurality of active regions AA separated from each other by a isolation structure 112. The dummy region A3 has a dummy pattern AD. In some embodiments, the semiconductor structure further includes a plurality of gate contacts 150 located in the peripheral region A2, and each gate contact 150 is electrically connected to a corresponding word line WL.

Each word line WL is located on the substrate 100 and extends along a first direction D1, and the word lines WL spaced apart at intervals along a second direction D2 that is different from the first direction D1. In this embodiment, the second direction D2 is perpendicular to the first direction D1. Each active region AA substantially extends along a direction DA, which is different from both the first direction D1 and the second direction D2. The dummy pattern AD, for example, extends along the second direction D2 and may be located on the opposite sides of the array region A1 (only one side is shown in the figure). Specifically, the dummy pattern AD may be located between the array region A1 and a side of the peripheral region A2 where gate contacts 150 are disposed. The dummy pattern AD may be connected to some active regions AA located at the edge of the array region A1 to prevent peeling, collapse or bending of the active regions AA, thereby facilitating alignment of the active regions AA with subsequent formed word lines WL.

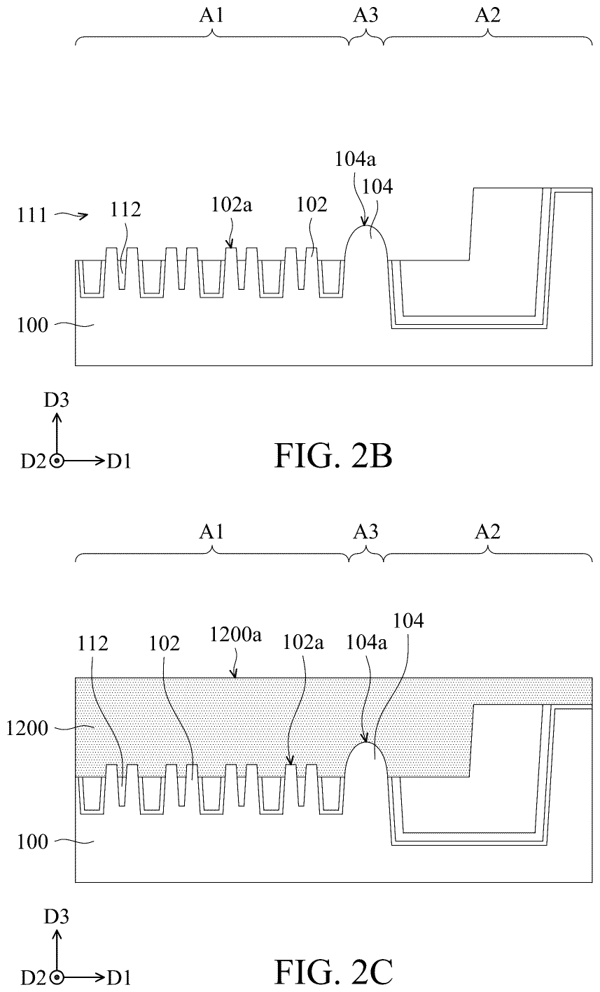

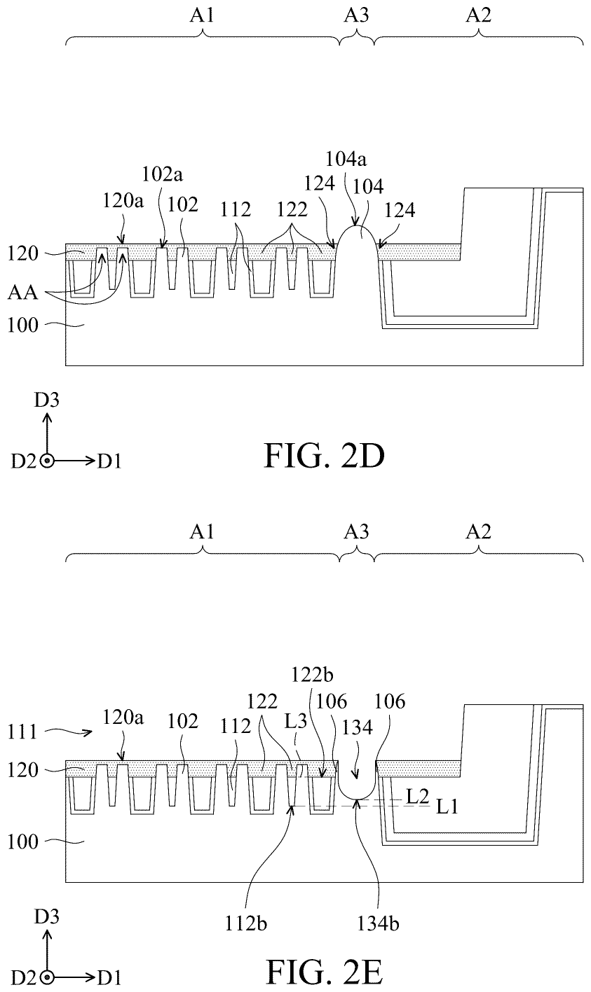

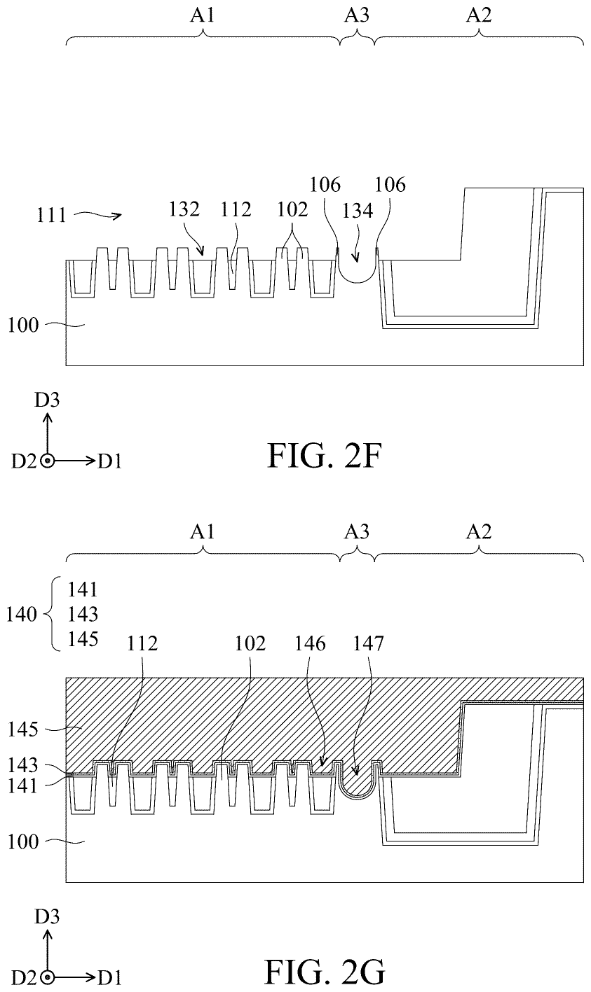

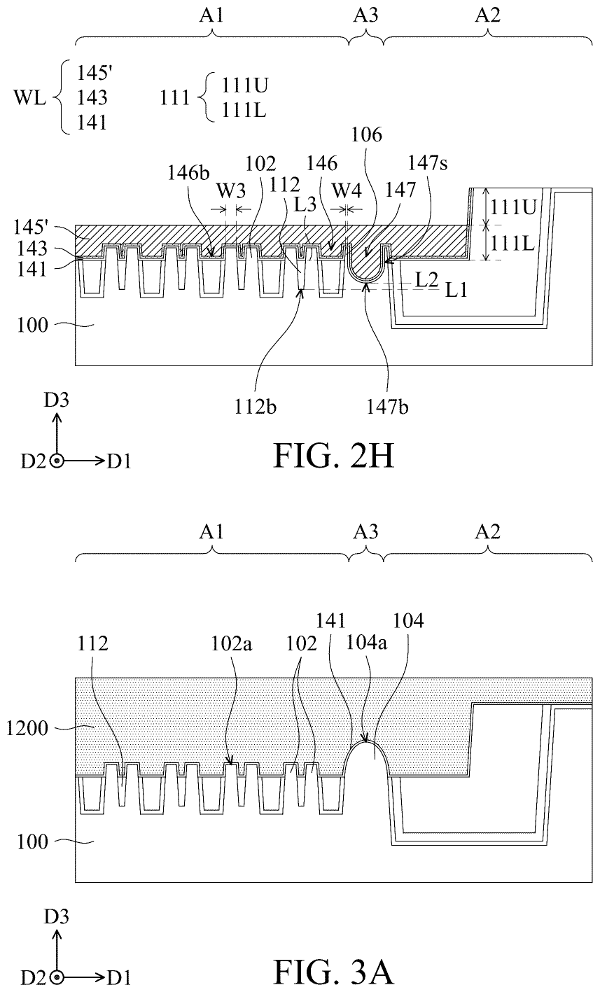

Furthermore, in this embodiment, the dummy pattern AD has a plurality of dummy concavities 134 (FIG. 2E) extending into the substrate 100 (i.e., along a third direction D3), and the dummy concavities 134 spaced apart at intervals along the second direction D2. Each word line WL has a dummy extending portion 147 that fills a corresponding dummy concavity 134. That is, the dummy extending portion 147 extend into the substrate 100. Each dummy extending portion 147 is spaced apart by a distance from the corresponding gate contact 150, to which it is electrically connected, along the first direction D1.

FIGS. 2A-2H are, for example, cross-sectional views taken along the line C-C in FIG. 1. Referring to FIG. 2A, isolation structures 112 are formed in the substrate 100. The isolation structures 112 surround and define the active regions AA and the dummy pattern AD. The substrate 100 may include a semiconductor material, such as silicon, gallium arsenide, gallium nitride, germanium silicide, or a combination thereof. In some other embodiments, the substrate 100 is a silicon-on-insulator (SOI) layer. The isolation structure 112 may include silicon oxide, silicon nitride, other suitable insulating materials, or a combination thereof.

Subsequently, referring to FIG. 1 and FIG. 2B, a plurality of gate trenches 111 are formed in the isolation structure 112 and the substrate 100, each corresponding to one of the word lines WL. Owing to the etching selectivity, the isolation structure 112 is etched to a greater depth than the substrate 100 during the formation of the gate trenches 111. As a result, at the bottom of the gate trenches 111, the top surface of the substrate 100 is higher than the top surface of the isolation structure 112. In this embodiment, within the gate trenches 111, the substrate 100 includes a plurality of first protrusions 102 located in the array region A1 and a plurality of second protrusions 104 located in the dummy region A3. Furthermore, due to the etching load effect, the substrate 100 in the dummy region A3 and the peripheral region A2 undergoes less etching than that in the array region A1 during the formation of the gate trenches 111. Therefore, within the gate trenches 111, the top surface 104a of the substrate 100 located in the dummy region A3 (i.e., the second protrusion 104) is higher than the top surface 102a of the substrate 100 located in the array region A1 (i.e., the first protrusion 102).

Next, referring to FIG. 2C, a sacrificial material layer 1200 is filled into the gate trenches 111 such that the sacrificial material layer 1200 covers the first protrusions 102 and the second protrusions 104. In one embodiment, the sacrificial material layer 1200 fills the gaps between the first protrusions 102, as well as the gaps between the second protrusions 104 and the adjacent first protrusions 102. The sacrificial material layer 1200 is, for example, over-deposited, such that it not only fills the gate trenches 111, but also extends over the top surface of the substrate 100 in the peripheral region A2, thereby blanketly covering the top surface of the substrate 100. Accordingly, the top surface 1200a of the sacrificial material layer 1200 is a flat surface. In some embodiments, the material of the sacrificial material layer 1200 is different from that of the isolation structure 112 and the substrate 100. For example, the sacrificial material layer 1200 may include a material with high fluidity, such as a carbon-containing material. In this example, the sacrificial material layer 1200 may be a spin-on carbon (SOC) layer.

As shown in FIG. 2D, a portion of the sacrificial material layer 1200 is selectively removed such that the top surface 120a of the remaining sacrificial material layer 120 is positioned below the top surface 104a of the second protrusion 104, in accordance with certain embodiments. Therefore, a portion of the second protrusion 104 protrudes above the remaining sacrificial material layer 120. In the active area A1, the remaining sacrificial material layer 120 may have a continuous top surface 120a above the isolation structures 112 and the active regions AA, and the top surface 120a is lower than the top surface 104a of the second protrusion 104.

In some embodiments, the portion of the sacrificial material layer 1200 may be removed by an etching process, such as etch back. In some embodiments, the etching process may select a suitable etching selectivity, for example, the etching selectivity of the sacrificial material layer 1200 to the substrate 100 is 3:1, so as to reduce the impact on the second protrusions 104. More specifically, in some embodiments, the remaining sacrificial material layer 120 covers the first protrusions 102 and the top surface 120a is higher than the top surfaces 102a of the first protrusions 102. Furthermore, in some embodiments, the remaining sacrificial material layer 120 may form a sacrificial filling portion 122 between the first protrusions 102, as well as between the first protrusions 102 and the second protrusions 104 in the active regions AA.

Further, in some embodiments, when viewed from above the substrate 100, the remaining sacrificial material layer 120 includes ring portions 124. These ring portions 124 respectively surround the second protrusions 104 corresponding to each word line WL in the dummy pattern AD.

Further, in some implementations, the height of the remaining sacrificial material layer 120 and the height of the second protrusion 104 protruding above the remaining sacrificial material layer 120 can be controlled and adjusted based on the desired depth after the second protrusion 104 are subsequently recessed. However, the present disclosure is not limited thereto.

Next, referring to FIG. 2E, in the gate trench 111, the remaining sacrificial material layer 120 is used as an etching mask to perform an etching process (e.g., a dry etching process) on the second protrusions 104, thereby recessing the second protrusions 104 and forming dummy concavities 134. The recessed depth of the dummy concavities 134 is at least lower than the top surface 120a of the remaining sacrificial material layer 120, thereby preventing the subsequently formed word lines WL from being disconnected.

In some embodiments, the etching process performed on the second protrusions 104 may have high selectivity and hardly affects the remaining sacrificial material layer 120.

In some embodiments, each of the dummy concavities 134 has a U-shaped cross-sectional profile. However, the present disclosure is not limited thereto, and the dummy concavities 134 may have other cross-sectional profiles.

According to some embodiments, the depth of the dummy concavities 134 (e.g., line L2) may land at any level between the top surface 120a of the remaining sacrificial material layer 120 and the depth of the isolation structure 112 (e.g., line L1). In other words, the bottom surface 134b of the dummy concavities 134 is not lower than the bottom surface 112b of the isolation structure 112, and is not higher than the top surface 120a of the remaining sacrificial material layer 120. In a preferred embodiment, the depth of the dummy concavities 134 (e.g., line L2) may be substantially the same as the depth of the sacrificial filling portion 122 (e.g., line L3), or may exceed the depth of the sacrificial filling portion 122. In this embodiment, the bottom surface 134b of the dummy concavities 134 is lower than the bottom surface 122b of the sacrificial filling portion 122. Thereby, interference in the subsequently formed word lines WL can be further avoided, and the resistance of the word lines WL can be reduced.

Further, in some embodiments, while forming the dummy concavities 134, the dummy pattern AD in the gate trenches 111 may include a plurality of dummy protruding portions 106 to define the dummy concavities 134. The top surface of the dummy protruding portions 106 is not higher than the top surface 120a of the remaining sacrificial material layer 120, and may be, for example, substantially coplanar with the top surface of the first protrusions 102.

Subsequently, according to some embodiments, referring to FIG. 2F, in some embodiments, the remaining sacrificial material layer 120 may be removed by one or more process steps including an ashing process and an etching process to expose the first protrusions 102 located in the active area A1 and the dummy protruding portion 106 located in the dummy region A3 within the gate trenches 111.

According to some embodiments, referring to FIG. 2G, a gate material stack 140 is formed in the gate trenches 111 and the dummy concavities 134. In this example, the gate material stack 140 includes a gate dielectric layer 141, a gate barrier layer 143, and a gate electrode layer 145.

According to some embodiments, the gate dielectric layer 141 conformally covers the sidewalls and top surface of the first protrusions 102 and the sidewalls and bottom surface of the dummy concavities 134. The gate dielectric layer 141 may include silicon oxide, silicon nitride, other suitable dielectric materials, or a combination thereof. In one example, the gate dielectric layer 141 may be a multilayer structure of silicon oxide/silicon nitride/silicon oxide (ONO) or a multilayer structure of silicon nitride/silicon oxide/silicon nitride/silicon oxide/silicon nitride (NONON), but the present disclosure is not limited thereto.

According to some embodiments, the gate barrier layer 143 is conformally formed on the gate dielectric layer 141, above the first protrusions 102 and in the dummy concavities 134. The material of the gate barrier layer 143 may include a conductive metal, such as a metal, a metal alloy, a metal nitride or a metal silicide, such as titanium nitride, titanium silicon nitride (TiSiN), tantalum nitride (TaN), tungsten nitride (WN), tantalum (Ta), titanium (Ti), tungsten (W), ruthenium (Ru) or aluminum.

According to some embodiments, the gate electrode layer 145 is formed on the gate barrier layer 143. The gate electrode layer 145 is, for example, over-deposited, and not only fills the remaining space of the gate trenches 111, but also extends to the top surface of the substrate 100 in the peripheral region A2 to cover the top surface of the substrate 100. Accordingly, the top surface of the gate electrode layer 145 is a flat surface. The material of the gate electrode layer 145 may include a conductive metal, such as a metal, a metal alloy, a metal nitride or a metal silicide, such as tungsten, tantalum, titanium, ruthenium, aluminum, tungsten nitride, titanium nitride, titanium silicon nitride, tantalum nitride, or other suitable conductive materials. The material of the gate electrode layer 145 is different from that of the gate barrier layer 143. In some embodiments, the gate barrier layer 143 includes titanium nitride, while the gate electrode layer 145 includes tungsten.

Subsequently, referring to FIG. 2H, a portion of the gate material stack 140 is removed to recess the gate material stack 140 and form word lines WL. Each word line WL includes a dummy extension portion 147 that fills the dummy concavity 134.

In some embodiments, the step of removing the portion of the gate material stack 140 may include a chemical mechanical polishing (CMP) process, an etch-back process, or other suitable processes to remove the gate material stack 140 outside the gate trenches 111. Subsequently, the gate electrode layer 145 is recessed within the gate trenches 111 using, for example, a selective etching process, leaving the remaining gate electrode layer 145′ located at the lower portion 111L of the gate trenches 111.

In this example, the word line WL includes a gate dielectric layer 141, a gate barrier layer 143, and a gate electrode layer 145′ formed in the lower portion 111L of the gate trench 111. The dummy extension portions 147 of the word lines WL in the dummy concavities 134 also include the gate dielectric layer 141, the gate barrier layer 143, and the gate electrode layer 145′.

Subsequently, an insulating layer (not shown) may be formed on the word line WL to fill the gate trench 111, so as to form buried word line WL. The material of the insulating layer is, for example, silicon nitride or other suitable insulating materials. In some other embodiments, the word line WL may include the gate dielectric layer 141, the gate barrier layer 143, the gate electrode layer 145, and a work function layer formed in sequence. After forming the buried word lines WL, subsequent processes may be performed to fabricate other elements of the semiconductor structure, such as forming bit lines (not shown) over the word lines WL, an interlayer dielectric layer (not shown) to cover the bit lines, gate contacts 150, capacitors (not shown), metal layers (not shown), and other known components to complete the fabrication of a memory device (e.g., DRAM). The bit line can extend in the second direction D2, for example, which can be perpendicular to the extending direction (the first direction D1) of the word line WL. Furthermore, the gate contacts 150 as shown in FIG. 1 may be located in the peripheral region A2 and may pass through the interlayer dielectric layer to be electrically connected to the corresponding word lines WL thereunder, respectively.

According to the semiconductor structure of the present invention, as shown in FIG. 2H, the substrate 100 has the first protrusions 102 located in the active regions AA and the dummy protruding portions 106 located in the dummy region A3, and the word lines WL include filling portions 146 formed between these first protrusions 102 and dummy extension portions 147 formed between these dummy protruding portions 106. In this embodiment, the width W3 of the first protrusion 102 in the first direction D1 may be greater than the width W4 of the dummy protruding portions 106 in the first direction D1. Each dummy extension portions 147 may (but is not limited to) have a U-shaped cross-sectional profile. Furthermore, as shown in FIG. 1, each dummy extension portion 147 may have a circular top surface, but the present disclosure is not limited thereto. The top surface of the dummy extension portions 147 may also be an ellipse, a quadrilateral, a polygon, or shapes similar to the above. According to the above-mentioned embodiment, the gate material stack 140 may be continuously filled into the gate trench 111. That is, the gate material stack 140 extends continuously in the first direction D1, ensuring that the word line WL remains uninterrupted between the array region A1 and the peripheral region A2.

Further, according to some embodiments, the depth of the dummy extension portions 147 (e.g., line L2) may land at any level between the depth of filling portion 146 (e.g., line L3) and the depth of isolation structure 112 (e.g., line L1). In other words, the bottom surface 147b of the dummy extension portions 147 is not lower than the bottom surface 112b of the isolation structure 112, and is not higher than the bottom surface 146b of the filling portions 146. In a preferred embodiment, the depth of the dummy extension portions 147 (e.g., line L2) may be substantially the same as the depth of the filling portions 146 (e.g., line L3), or may exceed the depth of the filling portions 146. In this embodiment, the bottom surface 147b of the dummy extension portions 147 is lower than the bottom surface 146b of the filling portions 146. Thereby, interference in the word lines WL can be further avoided, and the resistance of the word line WL can be reduced.

As shown in FIG. 1, each word line WL has a width of W1 in the second direction D2, the dummy pattern AD has a width of W5 in the first direction D1, and the top surface of the dummy extension portions 147 has a critical dimension W2 less than or equal to the width W1 in the second direction D2, and has a critical dimension W6 less than or equal to the width W5 in the first direction D1.

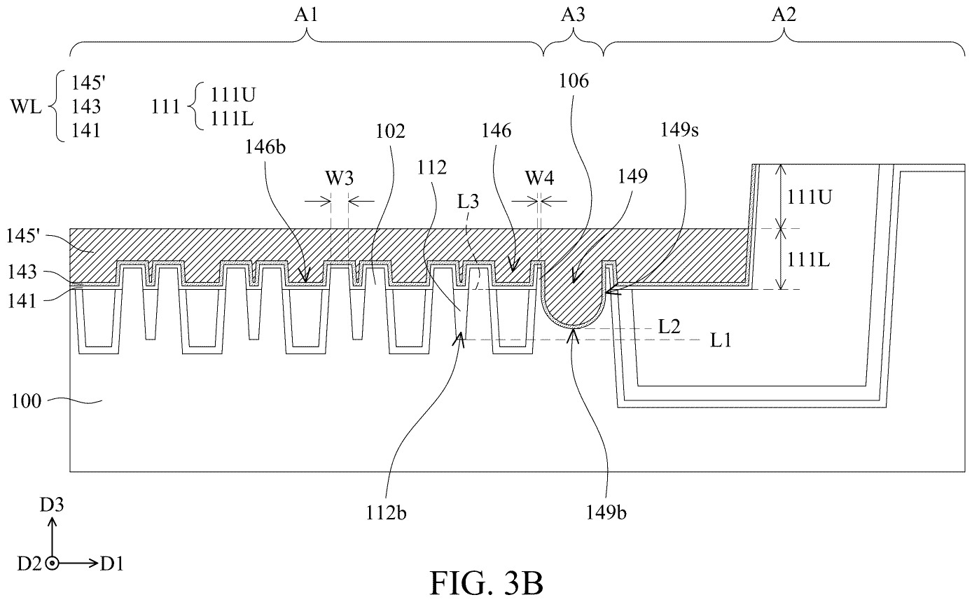

In addition, according to the method of manufacturing the semiconductor structure proposed in the first embodiment, after removing the remaining sacrificial material layer 120 (FIG. 2F), the gate dielectric layer 141, the gate barrier layer 143, and the gate electrode layer 145 are deposited in sequence (FIG. 2G). However, the manufacturing method disclosed herein is not limited to the above sequence. In the second embodiment of the present disclosure, as shown in FIG. 3A, after forming the gate trenches 111 (FIG. 2B), the gate dielectric layer 141 may be deposited first, and then the sacrificial material layer 1200 may be deposited on the gate dielectric layer 141. Next, the steps shown in FIGS. 2D to 2F are performed to form the dummy concavities 134 and remove the remaining sacrificial material layer 120, among other steps.

FIGS. 3A to 3B are, for example, cross-sectional views taken along the section line C-C in FIG. 1. Components in FIGS. 3A to 3B that are identical or similar to those in FIGS. 1 and 2A to 2H are denoted by identical or similar reference numbers, and the relevant details may be understood by referring to the contents of these components in the above embodiments, which will not be repeated herein.

Different from the embodiment shown in FIG. 2G, in this example, after forming the dummy concavities 134, a gate barrier layer 143 and a gate electrode layer 145 are formed in the gate trenches 111 and the dummy concavities 134, without including a gate dielectric layer 141. Thereafter, referring to FIG. 3B, the gate electrode layer 145 in the gate trenches 111 is recessed, and a portion of the gate electrode layer 145′ is left at the lower portion 111L of the gate trenches 111 to form a buried word lines WL. In each gate trench 111, each word line WL includes a dummy extension portion 149 that fills the dummy concavity 134.

It is worth noting that in the second embodiment, in the step of recessing the second protrusions 104 to form the dummy concavities 134, the gate dielectric layer 141 located on the second protrusions 104 is removed at the same time, and the remaining portion of the gate dielectric layer 141 covers the substrate 100 outside the second protrusions 104, for example, covering the first protrusions 102 and the dummy protruding portion 106 (as shown in FIG. 3B). In other words, the gate dielectric layer 141 does not exist in the dummy concavities 134. That is, the dummy extension portion 149 include the gate barrier layer 143 and the gate electrode layer 145′, but does not include the gate dielectric layer 141.

In summary, according to some embodiments of the present disclosure, a method for manufacturing a semiconductor structure is provided, prior to depositing a gate material stack in the gate trenches, relatively protrusions (such as a second protrusions) in the gate trenches within the dummy pattern is first recessed. Therefore, after the gate material stack is filled into the gate trenches and a portion of the gate material stack is recessed, word lines can be continuously formed in the gate trenches, respectively. Therefore, the semiconductor structure and the manufacturing method thereof disclosed in the present disclosure solve the problem of word line disconnection in the prior art and improve the yield of the semiconductor structure. Furthermore, according to some embodiments of the present disclosure, a sacrificial material layer is formed on the substrate and partially removed, so that the remaining sacrificial material layer exposes the relatively protrusions (such as the second protrusions), and the remaining sacrificial material layer is used as an etching mask to recess the second protrusions. Therefore, the method proposed in the embodiment is simple in manufacturing, compatible with the existing semiconductor process, and suitable for mass production.

Furthermore, the present disclosure is suitable for manufacturing miniaturized semiconductor structures, which increases the total number of dies on a wafer. As a result, it reduces the production cost and energy consumption of manufacturing a single IC, as well as the energy consumption in subsequent packaging, thereby reducing carbon emissions in the production process of semiconductor structures. In addition, since the yield of the semiconductor structure is improved, the present disclosure contributes to greener semiconductor technology.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate, comprising:
an array region having a plurality of active regions separated from each other by an isolation structure;
a periphery region surrounding the array region; and
a dummy region between the array region and the periphery region, having a dummy pattern; and
a plurality of word lines buried in the substrate, wherein each of the word lines extends in a first direction, and the word lines are arranged in a second direction, wherein each of the word lines has a dummy extending portion that extends into the substrate at an intersection with the dummy pattern, and the dummy extending portions of the word lines are arranged in the second direction.

2. The semiconductor structure of claim 1, wherein each of the word lines extends across the array region and the peripheral region and is electrically connected to a gate contact located in the peripheral region, the dummy pattern has a plurality of dummy concavities, and each of the dummy extending portions is filled into one of the dummy concavities.

3. The semiconductor structure of claim 2, wherein the substrate has a plurality of protruding portions located in the array region, and the dummy pattern comprises a plurality of dummy protruding portions surrounding the dummy extending portions, respectively, wherein each of the word lines covers the dummy protruding portions and the protruding portions.

4. The semiconductor structure of claim 3, wherein a width of one of the protruding portions in the first direction is greater than a width of one of the dummy protruding portions in the first direction.

5. The semiconductor structure of claim 1, wherein a bottom surface of each of the dummy extending portions is not lower than a bottom surface of the isolation structure.

6. The semiconductor structure of claim 5, wherein the substrate has a plurality of protruding portions located in the array region, each of the word lines has a filling portion between the protruding portions, and a bottom surface of each of the dummy extending portions is not higher than a bottom surface of the filling portion.

7. The semiconductor structure of claim 1, wherein each of the word lines has a first width in the second direction, the dummy pattern has a second width in the first direction, and a top surface of the dummy extending portion has a first critical dimension in the second direction that is less than or equal to the first width, and has a second critical dimension in the first direction that is less than or equal to the second width.

8. The semiconductor structure of claim 1, further comprising:
a plurality of gate contacts in the peripheral region and electrically connected to the word lines, respectively, wherein each of the dummy extending portions is spaced apart by a distance from the corresponding gate contact in the first direction.

9. The semiconductor structure of claim 8, wherein the dummy pattern is connected to the active regions located at an edge of the array region.

10. The semiconductor structure of claim 1, wherein the dummy extending portion do not have a gate dielectric layer.

11. A method of manufacturing a semiconductor structure, comprising:
providing a substrate, the substrate comprising:
an array region having a plurality of active regions separated from each other by an isolation structure;
a periphery region surrounding the array region; and
a dummy region between the array region and the periphery region, having a dummy pattern; and
forming a plurality of word lines buried in the substrate, wherein each of the word lines extends in a first direction, and the word lines are arranged in a second direction, wherein each of the word lines has a dummy extending portion that extends into the substrate at the intersection with the dummy pattern, and the dummy extending portions of the word lines are arranged in the second direction.

12. The method of claim 11, wherein each of the word lines extends across the array region and the peripheral region and is electrically connected to a gate contact located in the peripheral region, and the dummy pattern has a plurality of dummy concavities, and each of the dummy extending portions is filled into one of the dummy concavities.

13. The method of claim 11, wherein the step of forming the word lines comprises:
forming a plurality of gate trenches in the isolation structure and the substrate, so that the substrate at a bottom portion of the gate trenches comprises a plurality of first protrusions located in the array region and a plurality of second protrusions located in the dummy pattern, and top surfaces of the second protrusions are higher than top surfaces of the first protrusions;
filling a sacrificial material layer in the gate trenches to cover the first protrusions and the second protrusions;
removing a portion of the sacrificial material layer so that a top surface of the remaining sacrificial material layer is lower than the top surfaces of the second protrusions;
using the remaining sacrificial material layer as a mask, recessing the second protrusions to form a plurality of dummy concavities in the dummy pattern; and
removing the remaining sacrificial material layer to expose the first protrusions and the dummy concavities in the gate trenches.

14. The method of claim 13, wherein the top surface of the remaining sacrificial material layer is higher than the top surfaces of the first protrusions.

15. The method of claim 13, wherein the remaining sacrificial material layer comprises a plurality of ring portions, and each of the ring portions surrounds one of the second protrusions.

16. The method of claim 13, wherein bottom surfaces of the dummy concavities are not lower than a bottom surface of the isolation structure.

17. The method of claim 16, wherein the remaining sacrificial material layer has a sacrificial filling portion between the first protrusions, wherein the bottom surfaces of the dummy concavities are not higher than a bottom surface of the sacrificial filling portion.

18. The method of claim 13, wherein after forming the gate trenches, the method further comprises:
forming a gate dielectric layer in the gate trenches, wherein the sacrificial material layer is formed on the gate dielectric layer.

19. The method of claim 13, wherein after removing the remaining sacrificial material layer, the step of forming the word lines further comprises:
depositing a gate dielectric layer in the gate trenches and the dummy concavities;
depositing a gate barrier layer on the gate dielectric layer; and
depositing a gate electrode layer on the gate barrier layer.

20. The method of claim 11, wherein the dummy pattern is connected to the active regions located at the edge of the array region.
